(19) United States
(12) Patent Application Publication
(10) Pub. No.: US 2018/0090319 A1
(43) Pub. Date: Mar. 29, 2018

(54) HARD MASK AND MANUFACTURING METHOD THEREOF

(71) Applicant: TOKYO ELECTRON LIMITED, Tokyo (JP)

(72) Inventors: Takahiro Miyahara, Nirasaki City (JP); Hiroki Murakami, Nirasaki City (JP)

(21) Appl. No.: 15/715,212

(22) Filed: Sep. 26, 2017

(30) Foreign Application Priority Data
Sep. 29, 2016 (JP) 2016-190910

(51) Int. Cl. H01L 21/033; H01L 21/311; C23C 16/50; C23C 16/46; C23C 16/38

(52) U.S. Cl. CPC H01L 21/0337; H01L 21/31116; C23C 16/38; C23C 16/50; C23C 16/46; H01L 21/31144

(57) ABSTRACT

There is provided a hard mask used in forming a recess having a depth of 500 nm or more by dry etching. The hard mask includes a boron-based film formed as an etching mask on a film including a SiO₂ film. Further, there is provided a method of forming the hard mask as the etching mask on a substrate to be processed having the film including the SiO₂ film. The etching mask is for forming a recess having a depth of 500 nm or more by dry etching. The method includes forming a boron-based film by CVD by supplying at least a boron-containing gas to a surface of the film including the SiO₂ film while heating the substrate to a predetermined temperature.

### CROSS-REFERENCE TO RELATED APPLICATION

This application is based upon and claims the benefit of priority from Japanese Patent Application No. 2016-190910, filed on Sep. 29, 2016, the entire contents of which are incorporated herein by reference.

### TECHNICAL FIELD

The present disclosure relates to a hard mask and a manufacturing method thereof.

### BACKGROUND

In recent years, along with the progress in a technique of 3D structuring and miniaturizing of semiconductor devices, there is a need for a process in which a deep trench of 500 nm or more, for example, 1 to 5 μm, is formed in a film including a SiO₂ film of a semiconductor substrate as a substrate to be processed by dry etching using a hard mask.

On the other hand, an amorphous silicon film or an amorphous carbon film is known as a hard mask used for forming a recess such as a trench or the like in a SiO₂ film.

When forming the aforementioned deep trench having a depth of 500 nm or more, for example, 1 to 5 μm by dry etching, it is necessary to suppress a width of etching to be as narrow as possible, about several tens of nm.

However, the amorphous silicon or the amorphous carbon conventionally used as a hard mask has insufficient selectivity with respect to a SiO₂ film. When etching is deeply performed in the vertical direction, the etching progresses little by little in the lateral direction. As a result, a width of a trench widens.

### SUMMARY

Some embodiments of the present disclosure provide a hard mask and a hard mask manufacturing method which are capable of suppressing the widening of a width of a recess when forming a deep recess of 500 nm or more in a film including a SiO₂ film.

According to one embodiment of the present disclosure, there is provided a hard mask used in forming a recess having a depth of 500 nm or more by dry etching, the hard mask including a boron-based film formed as an etching mask on a film including a SiO₂ film.

According to another embodiment of the present disclosure, there is provided a method of forming a hard mask as an etching mask on a substrate to be processed having a film including a SiO₂ film, the etching mask for forming a recess having a depth of 500 nm or more by dry etching, the method including forming a boron-based film by CVD by supplying at least a boron-containing gas to a surface of the film including the SiO₂ film while heating the substrate to a predetermined temperature.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIGS. 1A and 1B are sectional views for explaining an example in which a trench is formed by dry etching using a hard mask according to an embodiment of the present disclosure.

FIGS. 2A and 2B are sectional views for explaining an example in which a trench is formed by dry etching using a conventional hard mask.

FIG. 3 is a view showing a selection ratio of a SiO₂ film to each film when trench etching is performed under DRAM conditions.

FIG. 4 is a view showing a selection ratio of a SiO₂ film to each film when trench etching is performed under NAND conditions.

FIG. 5 is a vertical sectional view showing a first example of a boron-based film forming apparatus for manufacturing a hard mask according to an embodiment of the present disclosure.

FIG. 6 is a vertical sectional view showing a second example of a boron-based film forming apparatus for manufacturing a hard mask according to an embodiment of the present disclosure.

FIG. 7 is a timing chart for explaining an example of a film forming sequence of the film forming apparatus of the first example or the film forming apparatus of the second example.

FIG. 8 is a view showing the relationship between a film formation time and a film thickness when a boron film as a boron-based film is formed by the film forming apparatus of the first example using a B₂H₆ gas as a boron-containing gas.

FIG. 9 is a view showing a depth direction profile of a film measured by an XPS when a boron film as a boron-based film is formed by the film forming apparatus of the first example using a B₂H₆ gas as a boron-containing gas.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Hard Mask

The hard mask according to the present embodiment is made of a boron-based film and is typically a CVD film. The boron-based film may be a boron film composed of boron and inevitable impurities, or may be a doped film obtained by doping a boron film with a predetermined element. The inevitable impurities may include hydrogen (H), oxygen (O), carbon (C) and the like depending on the raw material. As the doping element, one or more elements selected from Si, N, C, a halogen element and the like may be used. As the doped film, for example, a BSi film, a BN film or the like is formed. The content of the doping element is preferably 50 at % or less.

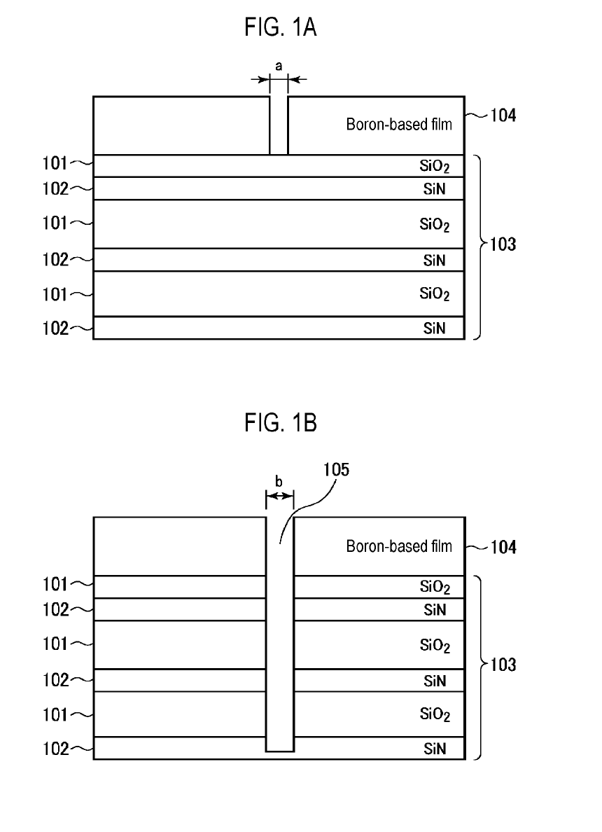

FIGS. 1A and 1B are sectional views for explaining an example in which a trench is formed by dry etching using a hard mask according to an embodiment of the present disclosure.

In FIGS. 1A and 1B, the hard mask of the present embodiment is applied to a 3D device manufacturing process. A hard mask 104 composed of a boron-based film is formed on a thick laminated film 103 obtained by repeatedly laminating a SiO₂ film 101 and a SiN film 102 plural times (FIG. 1A). A trench 105 having a thickness of 500 nm or more, for example, 1 to 5 μm is formed in the laminated film 103 in the depth direction by using the hard mask 104 as an etching mask (FIG. 1B).

At this time, it is difficult to etch the boron-based film under the etching conditions of the SiO₂ film. The SiO₂ film can be etched with high selectivity with respect to the boron-based film. Therefore, even if a depth of the trench 105 is 500 nm or more, it is possible to prevent a width b of the trench 105 from widening with respect to an opening width a of the hard mask 104 made of the boron-based film.

Among the boron-based films, a boron film composed of boron and inevitable impurities is most difficult to be etched under the etching conditions of the SiO₂ film and shows good performance as a hard mask. However, by using a doped film such as a BSi film, a BN film or the like doped with Si, N or the like as the boron-based film, it is possible to enhance the stability of the film and the smoothness of the film.

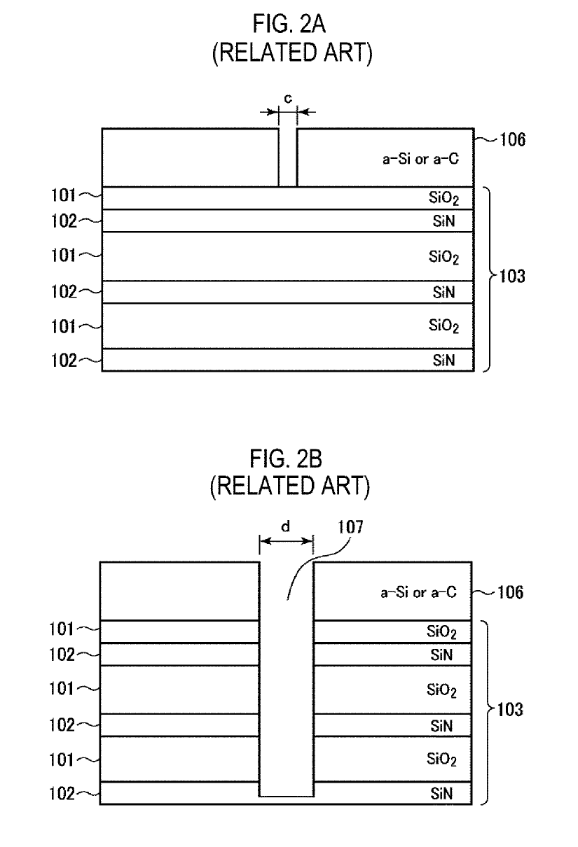

Conventionally, as shown in FIG. 2A, a hard mask 106 made of an amorphous silicon (a-Si) film or an amorphous carbon (a-C) film has been used. However, the amorphous carbon (a-C) or the amorphous silicon (a-Si) film has insufficient selectivity with respect to the SiO₂ film. Thus, as shown in FIG. 2B, while forming a deep trench 107 having a depth of 500 nm or more, a width d of the trench 107 remarkably widens as compared with an initial opening width c of the hard mask 106 made of the amorphous silicon (a-Si) film or the amorphous carbon (a-C) film.

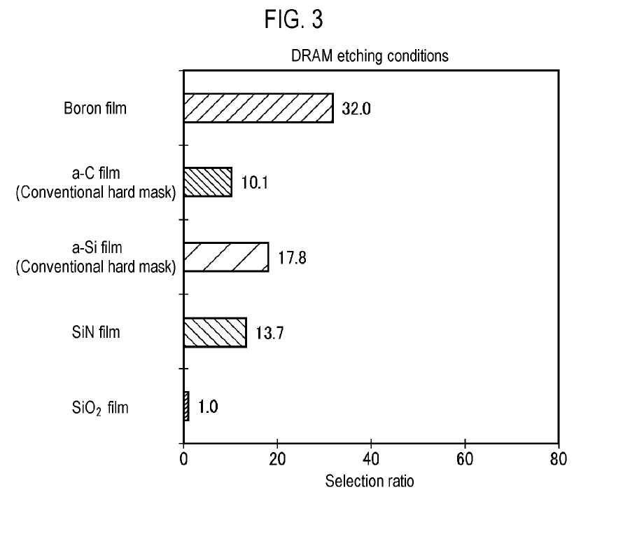

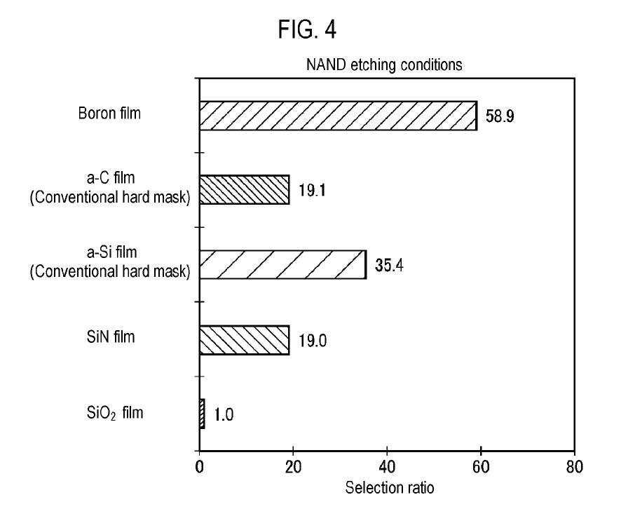

On the other hand, the boron film is more resistant to the SiO₂ film etching conditions (dry etching conditions) than the conventional a-C film and the conventional a-Si film. As shown in FIGS. 3 and 4, under the DRAM etching conditions and the NAND etching conditions, the selection ratios of the SiO₂ film to the boron film are 32.0 and 58.9, respectively, and are relatively high, as compared with the fact that the selection ratios to the a-C film used as a conventional hard mask material are 10.1 and 19.1, respectively, and the selection ratios to the a-Si film are 17.8 and 35.4, respectively. That is, under the SiO₂ film etching conditions, the boron film has a higher etching resistance than the a-Si film or the a-C film which is a conventional hard mask material. The doped film such as the BSi film, the BN film or the like also have etching characteristics conforming to those of the boron film. Therefore, by using the hard mask 104 made of the boron-based film, even if the depth of the trench is 500 nm or more, it is possible to prevent the problem of widening of the trench width as in the case of using a conventional hard mask made of the a-Si film or the a-C film. In the case where the boron-based film is a doped film, the content of a doping element is preferably 50 at % or less as described above from the viewpoint of maintaining a good etching resistance.

### Hard Mask Manufacturing Method

A hard mask made of such a boron-based film can be manufactured by forming a boron-based film by CVD. In the case where the boron-based film is a boron film, a substrate to be processed, for example, a semiconductor wafer is accommodated in a predetermined processing container. The inside of the processing container is brought into a vacuum state with a predetermined pressure. The substrate to be processed is heated to a predetermined temperature. In this state, a boron-containing gas such as a film-forming source gas is supplied into the processing container. The boron-containing gas is pyrolized on the substrate to be processed. As a result, a boron film is formed on the substrate to be processed.

Examples of the boron-containing gas include a diborane (B₂H₆) gas, a boron trichloride (BCl₃) gas, an alkylborane-based gas, an aminoborane-based gas and the like. Examples of the alkylborane-based gas include a trimethylborane (B(CH₃)₃) gas, a triethylborane (B(C₂H₅)₃) gas, gases denoted by B(R1)(R2)(R3), B(R1)(R2)H and B(R1)H₂ (where R1, R2 and R3 are alkyl groups), and the like. Examples of the aminoborane-based gas include an aminoborane (NH₂BH₂) gas, a tris(dimethylamino)borane (B(N(CH₃)₂)₃) gas and the like. Among these gases, the B₂H₆ gas may be suitably used.

The temperature at the time of forming the boron film by CVD is preferably in a range of 200 to 500 degrees C. When the boron-containing gas is a B₂H₆ gas, the temperature is more preferably 200 to 300 degrees C. The internal pressure of the processing container at this time is preferably 13.33 to 1,333 Pa (0.1 to 10 Torr).

When the boron-based film is a doped film doped with a predetermined element, a substrate to be processed, for example, a semiconductor wafer is accommodated in a predetermined processing container. The inside of the processing container is brought into a vacuum state with a predetermined pressure. The substrate to be processed is heated to a predetermined temperature. In this state, a boron-containing gas as a film-forming source gas and a doping gas containing a doping element are supplied into the processing container. The boron-containing gas and the doping gas are caused to react on the substrate to be processed. As a result, a doped film obtained by doping the boron film with a predetermined element, for example, a BSi film or a BN film, is formed.

As the doping element, as described above, one or more kinds of Si, N, C, a halogen element and the like may be used. When the doping element is Si, a Si-containing gas such as a monosilane (SiH₄) gas, a disilane (Si₂H₆) gas, an aminosilane gas or the like may be used. When the doping element is N, an N-containing gas such as an ammonia (NH₃) gas, a hydrazine (N₂H₄) gas, an organic amine gas or the like may be used. When the doping element is C, a C-containing gas such as propane, ethylene, acetylene or the like may be used. When the doping element is a halogen element, a halogen-containing gas such as Cl₂, F₂, HCl or the like may be used. A preferred example may include a case where a BSi film is formed by using a SiH₄ gas or a Si₂H₆ gas for doping Si as a doping gas or a case where a BN film is formed by using an NH₃ gas for doping N as a doping gas. In the case of forming a doped film, the flow rate ratio of the boron-containing gas and the doping gas is adjusted so that the doping elements are doped at a predetermined ratio.

The temperature at the time of forming the doped film as the boron-based film by CVD is preferably in a range of 200 to 500 degrees C. When the boron-containing gas is a B₂H₆ gas, the temperature is more preferably in a range of 200 to 300 degrees C. The internal pressure of the processing container at this time is preferably 13.33 to 1,333 Pa (0.1 to 10 Torr).

### First Example of Film Forming Apparatus

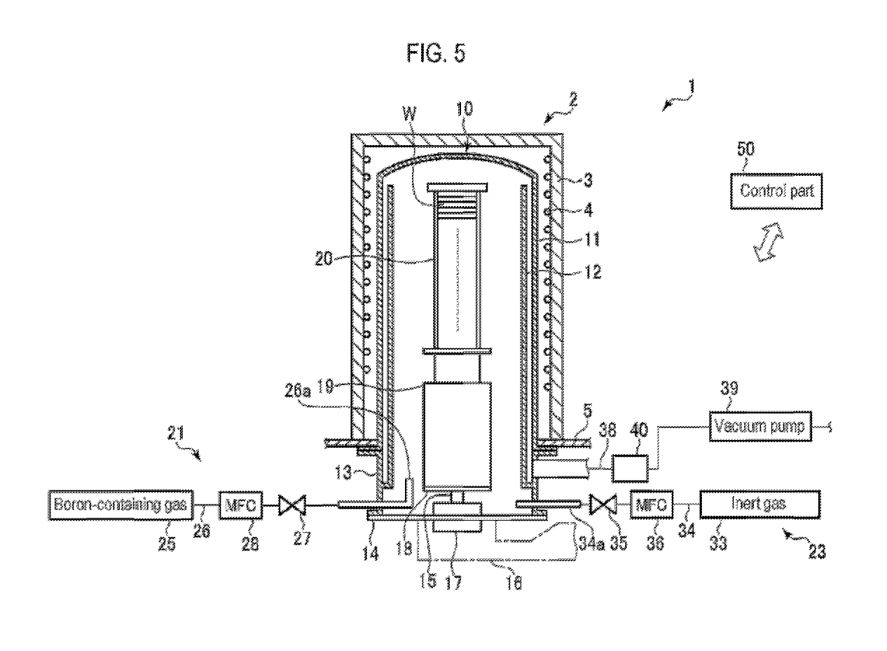

FIG. 5 is a vertical sectional view showing a first example of a boron-based film forming apparatus for manufacturing the hard mask of the present embodiment, in which view there is shown a case where a boron film is formed as a boron-based film.

The film forming apparatus 1 of a first example is configured as a batch type processing apparatus capable of processing a plurality of substrates, for example, 50 to 150 substrates to be processed at a time. The film forming apparatus 1 is provided with a heating furnace 2 that includes a tubular heat insulator 3 having a ceiling portion, and a heater 4 provided on an inner peripheral surface of the heat insulator 3. The heating furnace 2 is installed on a base plate 5.

Inside the heating furnace 2, there is inserted a processing container 10 of a double tube structure that includes an outer tube 11 made of, for example, quartz and closed at an upper end thereof, and an inner tube 12 concentrically disposed inside the outer tube 11 and made of, for example, quartz. The heater 4 is provided so as to surround the outside of the processing container 10.

The outer tube 11 and the inner tube 12 are respectively held at lower ends thereof by a tubular manifold 13 made of stainless steel or the like. At a lower end opening of the manifold 13, a cap part 14 for airtightly sealing the lower end opening is provided in an openable/closeable manner

A rotating shaft 15 rotatable in an airtight state kept by, for example, a magnetic seal is inserted in a central portion of the cap part 14. A lower end of the rotating shaft 15 is connected to a rotating mechanism 17 of an elevating table 16. An upper end of the rotating shaft 15 is fixed to a turntable 18. On the turntable 18, a quartz-made wafer boat 20 for holding semiconductor wafers (hereinafter simply referred to as wafers) as substrates to be processed is mounted via a heat insulating cylinder 19. The wafer boat 20 is configured to accommodate, for example, 50 to 150 wafers W stacked at a predetermined pitch.

The wafer boat 20 can be loaded into and unloaded from the processing container 10 by moving up and down the elevating table 16 with an elevating mechanism (not shown). When the wafer boat 20 is loaded into the processing container 10, the cap part 14 is brought into close contact with the manifold 13 so that an airtight seal is provided therebetween.

Further, the film forming apparatus 1 includes a boron-containing gas supply mechanism 21 for introducing a boron-containing gas which is a film-forming source gas, for example, a B₂H₆ gas, into the processing container 10, and an inert gas supply mechanism 23 for introducing an inert gas used as a purge gas or the like into the processing container 10.

The boron-containing gas supply mechanism 21 includes a boron-containing gas supply source 25 for supplying a boron-containing gas as a film-forming source gas, for example, a B₂H₆ gas, a film-forming gas pipe 26 for introducing a film-forming gas from the boron-containing gas supply source 25, and a quartz-made film-forming gas nozzle 26a connected to the film-forming gas pipe 26 and provided so as to penetrate a lower portion of a side wall of the manifold 13. In the film-forming gas pipe 26, an opening/closing valve 27 and a flow rate controller 28 such as a mass flow controller or the like are provided so as to supply the film-forming gas while controlling the flow rate thereof.

The inert gas supply mechanism 23 includes an inert gas supply source 33, an inert gas pipe 34 for introducing an inert gas from the inert gas supply source 33, and an inert gas nozzle 34a connected to the inert gas pipe 34 and provided so as to penetrate the lower portion of the side wall of the manifold 13. In the inert gas pipe 34, there are provided an opening/closing valve 35 and a flow rate controller 36 such as a mass flow controller or the like. As the inert gas, it may be possible to use an N₂ gas or a rare gas such as an Ar gas or the like.

An exhaust pipe 38 for discharging a process gas from a gap between the outer tube 11 and the inner tube 12 is connected to an upper portion of the side wall of the manifold 13. The exhaust pipe 38 is connected to a vacuum pump 39 for evacuating the interior of the processing container 10. A pressure regulating mechanism 40 including a pressure regulating valve and the like is provided in the exhaust pipe 38. While evacuating the interior of the processing container 10 with the vacuum pump 39, the internal pressure of the processing container 10 is adjusted to a predetermined pressure by the pressure regulating mechanism 40.

The film forming apparatus 1 includes a control part 50. The control part 50 includes a main control part having a computer (CPU) for controlling the respective constituent parts of the film forming apparatus 1, for example, the valves, the mass flow controllers, the heater power supply, the elevating mechanism and the like, an input device, an output device, a display device and a memory device. Parameters of various processes to be executed by the film forming apparatus 1 are stored in the memory device. A storage medium which stores programs, i.e., process recipes for controlling the processes executed in the film forming apparatus 1 is set in the memory device. The main control part calls out a predetermined process recipe stored in the storage medium and executes control so that a predetermined process is performed by the film forming apparatus 1 based on the predetermined process recipe.

### Second Example of Film Forming Apparatus

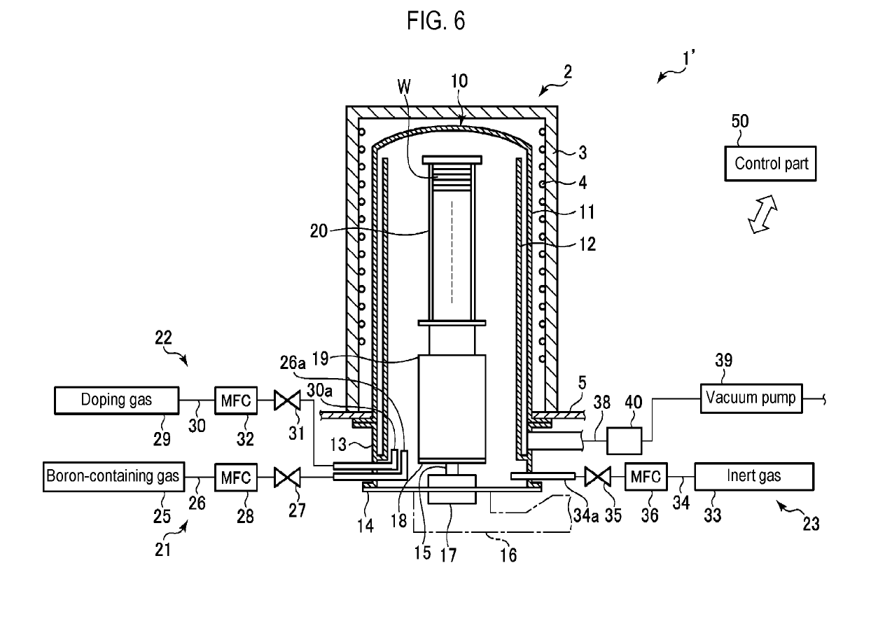

FIG. 6 is a vertical sectional view showing a second example of a boron-based film forming apparatus for manufacturing the hard mask of the present embodiment, in which view there is shown a case where a doped film obtained by doping the boron film with another element is formed as a boron-based film.

The film forming apparatus 1′ of a second example basically has the same configuration as the film forming apparatus 1 of the first example except that a doping gas supply mechanism 22 for supplying a doping gas is added.

The doping gas supply mechanism 22 includes a doping gas supply source 29 for supplying a doping gas such as a SiH₄ gas or an NH₃ gas described above, a doping gas pipe 30 for leading the doping gas from the doping gas supply source 29, and a doping gas nozzle 30a connected to the doping gas pipe 30 and provided to penetrate the lower portion of the side wall of the manifold 13. In the doping gas pipe 30, an opening/closing valve 31 and a flow rate controller 32 such as a mass flow controller or the like are provided so as to supply the doping gas while controlling the flow rate thereof. In addition to the boron-containing gas, the doping gas is supplied into the processing container 10 by the doping gas supply mechanism 22.

In the film forming apparatus 1 of the first example and the film forming apparatus 1′ of the second example, the boron-based film is formed under the control of the control part 50 as described above.

### Film Forming Sequence

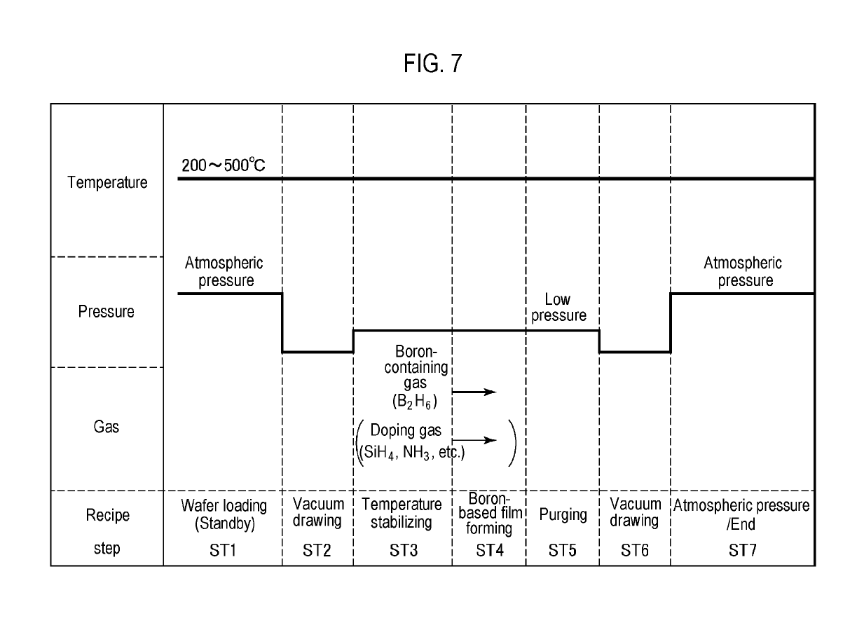

An example of a film forming sequence of the film forming apparatus 1 of the first example or the film forming apparatus 1′ of the second example will be described with reference to FIG. 7. FIG. 7 is a timing chart at the time of forming a boron-based film by the film forming apparatus 1 or the film forming apparatus 1′, showing a temperature, a pressure, introduced gases and recipe steps.

In the example of FIG. 7, first, an internal temperature of the processing container 10 is controlled to a predetermined temperature of 200 to 500 degrees C. depending on the kind of the boron-based film, and the wafer boat 20 holding a plurality of wafers W is inserted into the processing container 10 under the atmospheric pressure (ST1). Vacuum drawing is performed in this state to bring the inside of the processing container 10 into a vacuum state (ST2). Next, the interior of the processing container 10 is adjusted to a predetermined low pressure state, for example, 133.3 Pa (1.0 Torr), and the temperature of the wafers W is stabilized (ST3). In this state, a boron-containing gas such as a B₂H₆ gas or the like is introduced into the processing container 10 by the boron-containing gas supply mechanism 21, and a boron-based film (a boron film or a doped film) is formed on a surface of the wafer W by thermally decomposing the boron-containing gas on the surface of the wafer W or by CVD which introduces a doping gas, for example, a SiH₄ gas or an NH₃ gas, into the processing container 10 by the doping gas supply mechanism 22 and causes the boron-containing gas to react with the doping gas on the surface of the wafer W (ST4). Thereafter, an inert gas is supplied from the inert gas supply mechanism 23 into the processing container 10 to purge the interior of the processing container 10 (ST5). The interior of the processing container 10 is subsequently vacuum-drawn by the vacuum pump 39 (ST6). Thereafter, the internal pressure of the processing container 10 is restored to the atmospheric pressure, and the processing is terminated (ST7). When the boron-containing gas is a B₂H₆ gas, it is preferable to control the internal temperature of the processing container 10 to 200 to 300 degrees C.

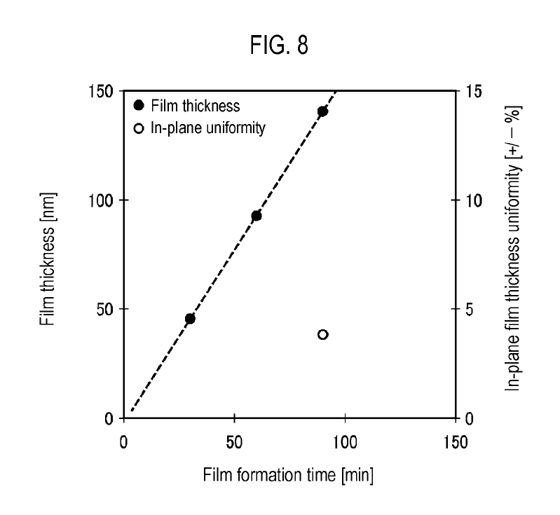

The relationship between the actual film formation time and the film thickness when a boron film such as a boron-based film is formed by the film forming apparatus of the first example using a B₂H₆ gas as a boron-containing gas is as shown in FIG. 8. As shown in FIG. 8, it was confirmed that a practical deposition rate is obtained. In FIG. 8, there is also shown the wafer in-plane uniformity. The in-plane uniformity was about 4% at the film formation time of about 90 min

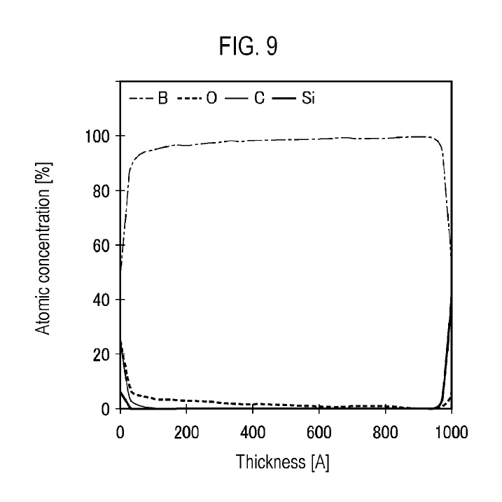

In addition, the profile in the depth direction of the film of the aforementioned case measured by an XPS is shown in FIG. 9. As shown in FIG. 9, it was confirmed that a boron film with little impurities can be obtained by forming the boron film using the B₂H₆ gas as the boron-containing gas. Although the XPS cannot detect hydrogen, in reality, the film contains a small amount of hydrogen.

It was found that, by using such a boron film or a doped film as a hard mask, the hard mask has high etching resistance when dry etching of the silicon oxide film (SiO₂ film) is performed and the film including the SiO₂ film can be etched with a high selection ratio. Therefore, when a deep trench having a thickness of 500 nm or more, specifically 1 μm or more, is formed in the film including the SiO₂ film, it is possible to enhance the effect of suppressing the widening of the width of the trench as compared with the conventional hard mask.

As the hard mask, a film in which a plasma modified layer may be formed on the surface of the boron-based film by forming the boron-based film and then treating the surface thereof with Ar plasma or H₂ plasma may be used. By performing the plasma processing in this manner, boron-boron bonding on the surface of the boron-based film is promoted, and a hard mask with high strength is obtained.

In addition, the boron-based film such as a boron film or the like is easily oxidized. The properties of the film are changed by oxidation. Therefore, when the hard mask is only the boron-based film, if the boron-based film is exposed to a plasma oxidizing atmosphere by, for example, forming a TEOS film on the boron-based film by plasma CVD, there is a concern that the performance of the boron-based film is deteriorated due to oxidation of the boron-based film. In such a case, it is preferable to form, as the hard mask, a protective layer having a high oxidation resistance on the surface of the boron-based film. As such a protective layer, a SiN film, a SiC film, a SiCN film, an a-Si film or the like may be suitably used.

### Other Applications

While the embodiments of the present disclosure have been described above, the present disclosure is not limited to the above-described embodiments. Various modifications may be made without departing from the spirit of the present disclosure.

In the above embodiments, the vertical batch type apparatus has been described as an example of the film forming apparatus for forming the boron-based film constituting the hard mask. However, other various film forming apparatuses such as a horizontal batch type apparatus and a single-wafer-type apparatus may be used. When plasma processing is performed on the surface of the boron-based film, it is preferable to use a single-wafer-type apparatus because plasma processing can be performed directly after film formation by using the single-wafer-type apparatus.

Although the hard mask is used for forming a trench in the above embodiment, the present disclosure may be applied to a case of forming not only a trench but also other recesses such as a hole or the like.

According to the present disclosure in some embodiments, it is possible to suppress the widening of a width of a recess when forming a deep recess having a depth of 500 nm or more in a film including a SiO₂ film.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A hard mask used in forming a recess having a depth of 500 nm or more by dry etching, the hard mask comprising:
a boron-based film formed as an etching mask on a film including a SiO₂ film.

2. The hard mask of claim 1, wherein the boron-based film is a boron film including boron and inevitable impurities.

3. The hard mask of claim 1, wherein the boron-based film is a doped film obtained by doping a boron film with a predetermined element.

4. The hard mask of claim 3, wherein the predetermined element includes one or more elements selected from a group consisting of Si, N, C and a halogen element.

5. The hard mask of claim 1, wherein the boron-based film is a CVD film.

6. The hard mask of claim 1, wherein a surface of the boron-based film includes a plasma-modified layer formed by Ar plasma or H₂ plasma.

7. The hard mask of claim 1, wherein a surface of the boron-based film includes a protective film for suppressing oxidation of boron.

8. The hard mask of claim 7, wherein the protective film is a film selected from a group consisting of a SiN film, a SiC film, a SiCN film and an amorphous silicon film.

9. A method of forming a hard mask as an etching mask on a substrate to be processed having a film including a SiO₂ film, the etching mask for forming a recess having a depth of 500 nm or more by dry etching, the method comprising:
forming a boron-based film by CVD by supplying at least a boron-containing gas to a surface of the film including the SiO₂ film while heating the substrate to a predetermined temperature.

10. The method of claim 9, wherein in the forming the boron-based film, a boron film as the boron-based film is formed by supplying only the boron-containing gas to the surface of the film including the SiO₂ film.

11. The method of claim 9, wherein in the forming the boron-based film, a doped film obtained by doping a boron film with a predetermined element is formed as the boron-based film by supplying the boron-containing gas and a doping gas for doping the predetermined element to the surface of the film including the SiO₂ film.

12. The method of claim 11, wherein the predetermined element includes one or more elements selected from a group consisting of Si, N, C and a halogen element, a Si-containing gas is used as the doping gas when the predetermined element is Si, an N-containing gas is used as the doping gas when the predetermined element is N, a C-containing gas is used as the doping gas when the predetermined element is C, and a halogen-containing gas is used as the doping gas when the predetermined element is the halogen element.

13. The method of claim 9, wherein the boron-containing gas is at least one selected from a group consisting of a diborane gas, a boron trichloride gas, an alkylborane gas and an aminoborane gas.

14. The method of claim 9, wherein the predetermined temperature of the substrate when forming the boron-based film ranges from 200 to 500 degrees C.

15. The method of claim 9, further comprising:
subjecting a surface of the boron-based film to plasma processing by Ar plasma or H₂ plasma.

16. The method of claim 9, further comprising:
forming a protective film for suppressing oxidation of boron on a surface of the boron-based film.

17. The method of claim 16, wherein the protective film is a film selected from a group consisting of a SiN film, a SiC film, a SiCN film and an amorphous silicon film.
